(19) United States
(12) Patent Application Publication
(10) Pub. No.: US 2009/0152023 A1
(43) Pub. Date: Jun. 18, 2009

(54) HYBRID TOUCH PANEL AND METHOD MAKING THEREOF

(75) Inventors: YU-CHOU YEH, Taoyuan Hsien (TW); KUO-YI YEN, Taoyuan Hsien (TW); YU-HONG YEN, Taoyuan Hsien (TW)

Correspondence Address: WPAT, PC, 7225 BEVERLY ST., ANNANDALE, VA, 22003, US

(73) Assignee: J TOUCH CORPORATION, Taoyuan Hsien (TW)

(21) Appl. No.: 12/016,281

(22) Filed: Jan. 18, 2008

(30) Foreign Application Priority Data
Dec. 12, 2007 (TW) 096147427

(51) Int. Cl. G06F 3/041; H05K 3/02

(52) U.S. Cl. 178/18.05; 29/847

(57) ABSTRACT

The present invention provides a hybrid touch panel, which comprises a first conductive module, a second conductive module, and a spacer layer. The first conductive module has a first conductive layer having at least a first resistive touching area, and at least a capacitive touching area. The second conductive module has a second conductive layer having at least a second resistive touching area corresponding to the first resistive touching area respectively. The spacer layer coupled to the first resistive touching area and the second resistive touching area has spacer dots disposed therebetween. The present invention further provides a method for making the hybrid touch panel, wherein the first resistive touching area and the capacitive touching area are formed on the first conductive layer simultaneously so as to integrate the resistive control and capacitive control on the same touch panel for increasing the diversity of the touching control.

### BACKGROUND OF THE INVENTION

1. Field of the Invention

This invention generally relates to a touch panel. The invention more particularly relates to a hybrid touch panel and a method for making the hybrid touch panel.

2. Description of the Related Art

In 1970, touch panel is originated for military usage in United States of America. Until 1980, technologies related to touch panel were published and utilized to be other applications. Now, touch panel is universal and applied to replace input device like keyboard or mouse. Especially, most of electrical equipments such as Automatic Teller Machine (ATM), Kiosks, Point of Service (POS), household appliances, industrial electronics and etc are equipped with touch panel and its technologies to make input easily. In addition, more and more the consumer products take this trend to make them thin, light, short and small to carry, for example, personal digital assistant (PDA), mobile phone, notebook, laptop, MP3 player and so on.

Generally speaking, there are two kinds of touch panel. One is resistive touch panel, and another is capacitive touch panel. Resistive touch panel is a mainstream in the market because of low cost. Resistive touch panels have a flexible top layer and a rigid bottom layer separated by insulating dots, with the inside surface of each layer coated with a transparent metal oxide. Material of the top layer and the bottom layer is polyethylene terephthalate (PET), while material of the inside surface of each layer is indium tin oxide (ITO). The resistive panel is placed on the liquid crystal display or the graphic device and being pressed by an object like a finger to make a touch point, the coordinate of the touch point is record in the touch screen device.

On the other hand, a capacitive touch screen panel is coated with a material, typically indium tin oxide or antinomy tin oxide that conducts a continuous electrical current across the sensor. The sensor therefore exhibits a precisely controlled field of stored electrons in both the horizontal and vertical axes—it achieves capacitance. The human body is also an electrical device which has stored electrons and therefore also exhibits capacitance. When the sensor's ‘normal’ capacitance field (its reference state) is altered by another capacitance field, i.e., someone's finger, electronic circuits located at each corner of the panel measure the resultant ‘distortion’ in the sine wave characteristics of the reference field and send the information about the event to the controller for mathematical processing. Capacitive sensors can either be touched with a bare finger or with a conductive device being held by a bare hand. Capacitive touch screens are not affected by outside elements and have high clarity, but their complex signal processing electronics increase their cost.

The resistive touch panel is economic for end user but it has a response time lower than the capacitive touch panel which could be applied to be a special input interface, like a gesture input. In this market, however, there is no product to fully utilize advantages of both.

It is understood that an integrated touch panel is needed in this market. Therefore, the present invention provides a hybrid touch panel and a method for making the hybrid touch panel.

### BRIEF SUMMARY OF THE INVENTION

To solve the disadvantage of the prior art. The present invention provides a hybrid touch panel which integrates resistive and capacitive touch panel for input as user's will.

To achieve these aspects mentioned above, the present invention provides a hybrid touch panel comprising a first conductive module including a first conductive layer having at least a first resistive touching area, and at least a capacitive touching area; a second conductive module including a second conductive layer having at least a second resistive touching area corresponding to the first resistive touching area respectively; and a spacer layer coupled to the first resistive touching area and the second resistive touching area has spacer dots disposed therebetween.

The present invention provides a method for making a hybrid touch panel, which comprises providing a base material having a first conductive layer; forming at least a first resistive touching area and at least a capacitive touching area by removing unnecessary conductive material on the first conductive layer, which constructs a first conductive module; providing a base material having a second conductive layer; forming at least a second resistive touch area corresponding to the first resistive touch area by removing unnecessary conductive material on the second conductive layer; forming an isolation layer on the second resistive touching area, which constructs a second conductive module; and binding the first conductive module and the second conductive module.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1A is a schematic diagram of a hybrid touch panel according to one embodiment of the present invention;

FIG. 1B is a cross-sectional view of a hybrid touch panel taken along the 1B-1B of FIG. 1A;

FIG. 2A is a cross-sectional view of a hybrid touch panel according to another embodiment of the present invention;

FIG. 2B is a schematic diagram of an isolating structure according to one embodiment of the present invention;

FIG. 3 is a cross-sectional view of a hybrid touch panel according to another embodiment of the present invention;

FIGS. 4A and 4B are schematic diagrams of a detection structure in the resistive touching area according to one embodiment of the present invention;

FIGS. 5A, 5B and 5C are schematic diagrams of a trench according to one embodiment of the present invention;

FIG. 6 is a schematic diagram of a hybrid touch panel according to yet another embodiment of the present invention;

FIG. 7A is a schematic diagram to combine a resistive touch panel with a capacitive touch panel according to one embodiment of the present invention;

FIG. 7B is a schematic diagram to combine a resistive touch panel with a capacitive touch panel according to another embodiment of the present invention; and

FIGS. 8A to 8I present a flow for illustration of making the hybrid touch panel according to one embodiment of the present invention.

### DETAILED DESCRIPTION OF THE INVENTION

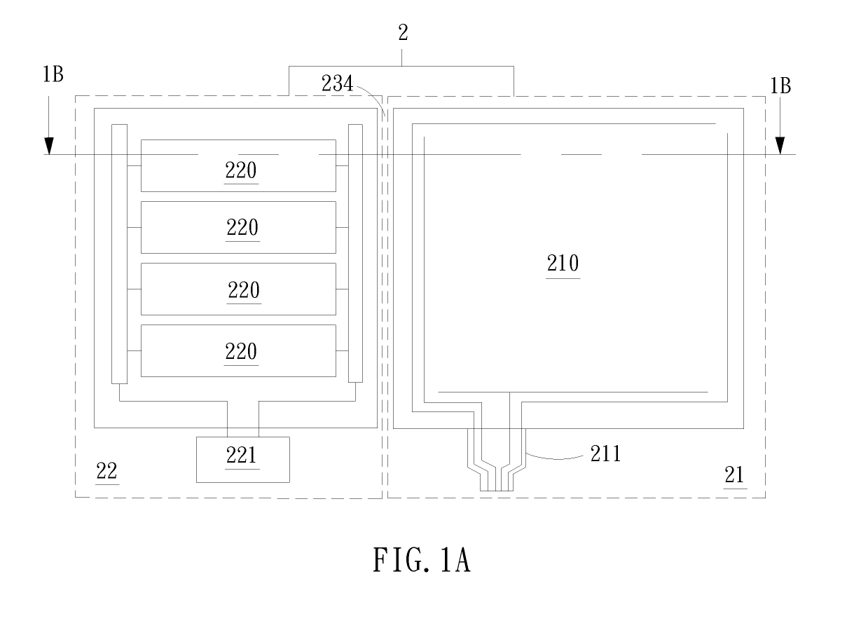

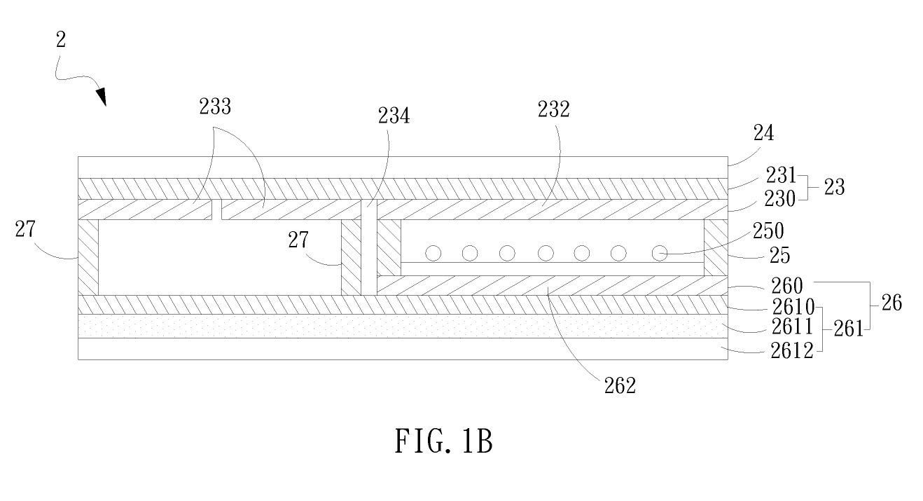

Several exemplary embodiments of the invention are described with reference to FIGS. 1A through 8I, which generally relate to a hybrid touch panel and a method for making a hybrid touch panel. It is to be understood that the following disclosure provides various different embodiments as examples for implementing different features of the invention. Specific examples of components and arrangements are described in the following to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various described embodiments and/or configurations.

Referring to FIG. 1A, it is a schematic diagram of a hybrid touch panel according to one embodiment of the present invention. In FIG. 1A, a hybrid touch panel 2 includes a resistive touch panel 21 and a capacitive touch panel 22. The resistive touch panel includes a touching area 210 for user input and a flexible printed circuit 211 electrically coupled to the touching area 210 for signal transmission. The capacitive touch panel includes a plurality of detecting area 220 and a transmission interface 221 for signal transmission. In this embodiment, there are only four lines in the resistive touch panel 21 but the person skilled in the art knows it could be five lines or eight lines to be implement.

Referring to FIG. 1B, it is a cross-sectional view of a hybrid touch panel taken along the 1B-1B of FIG. 1A. The hybrid touch panel 2 includes a first conductive module 23, a second conductive module 26 and a isolation structure 25. The first conductive module 23 includes a first conductive layer 230 which is defined two touching areas, the first resistive touching area 232 and capacitive touching area 233. There is a spacer layer 234 between the first resistive touching area 232 and the capacitive touching area 233. In this embodiment, material of the first conductive layer 230 could be a conductive polymeric material or transparent conductive oxides, wherein conductive polymeric material could be poly(3,4-ethylenedioxythiophene (PEDOT) and the transparent conductive oxides (TCO) could be indium tin oxide (ITO), antinomy tin oxide (ATO) or zinc oxide (ZnO), but not limited to. In this case, the conductive layer 21 is indium tin oxide. A base material 231 is formed on the first conductive layer 230 and the base material 231 could be conductive polymeric material, for example but not limited to, a polyester film. Besides, a transparent hard coat layer 24 such as polyester film is formed on the base material 231 to protect the first conductive module 23.

The second conductive module 26 includes a second conductive layer 260 which is defined a second resistive conductive touching area 262 corresponding to the first resistive touching area 232. The material of the second conductive layer 260 is the same as the first conductive layer 230. The isolation structure 25 is disposed between the second resistive touching area 262 and the first resistive touching area 232. The first resistive touching area 232, the second resistive touching area 262 and the isolation structure 25 construct a touching area 210 as shown in FIG. 1A. The isolation structure 25 includes spacer dots 250 to maintain space between the first resistive conductive area 232 and the second resistive touching area 262.

In addition, the second conductive module 26 comprises a base material 261 coupled to the second conductive layer 260. The base material 261 further comprises a substrate 2612, an optical adhesive layer 2611 and a conductive polymeric layer 2610. The material of substrate 2612 could be, but not limited to, polycarbonate. The optical adhesive layer 2611 is formed on the substrate 2612 while the conductive polymeric layer 2610 is formed on the optical adhesive layer 2611 and coupled to the second conductive layer 260. In this embodiment, the conductive polymeric layer 2610 is polyester. In another embodiment, the base material is polyester.

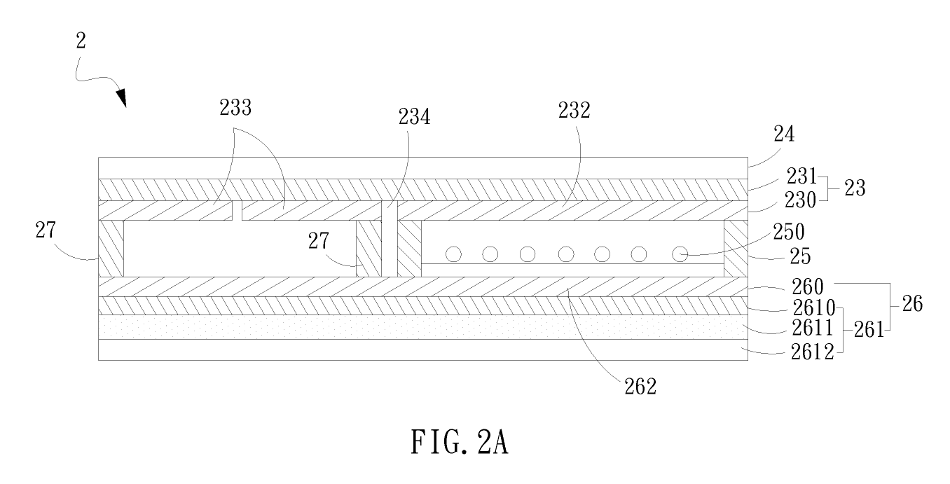

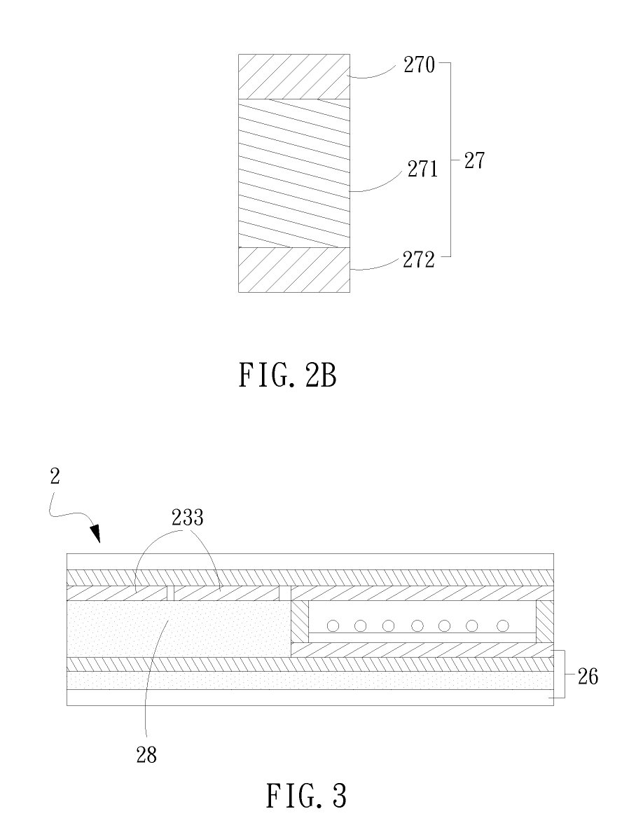

In FIG. 1B, an isolation structure 27 is further included between the first resistive touching area 233 and the base material of the second conductive module. Referring to FIG. 2A, it is a cross-sectional view of a hybrid touch panel according to another embodiment of the present invention. The second conductive layer 260 of the second conductive module 26 could be extended to correspond to the second resistive touching area 233. In FIG. 2B, the isolation structure 27 is composed by two conductive metal layer 270 and 272, such as silver. Further, an isolating layer 271 is included between conductive metal layer 270 and 272.

Referring to FIG. 3, a cross-sectional view of a hybrid touch panel according to another embodiment of the present invention. In this embodiment, the space between the first resistive touching area 232 and the second conductive module 26 is filled in an isolation material 28, such as an optical adhesive or UV adhesive.

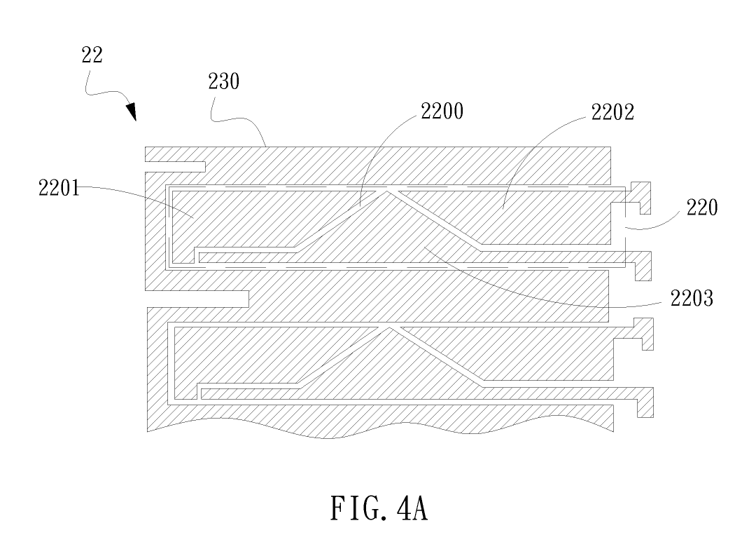

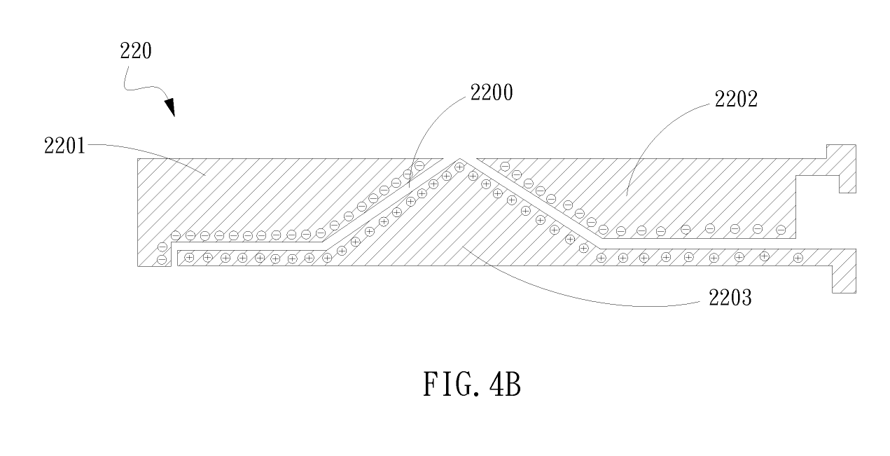

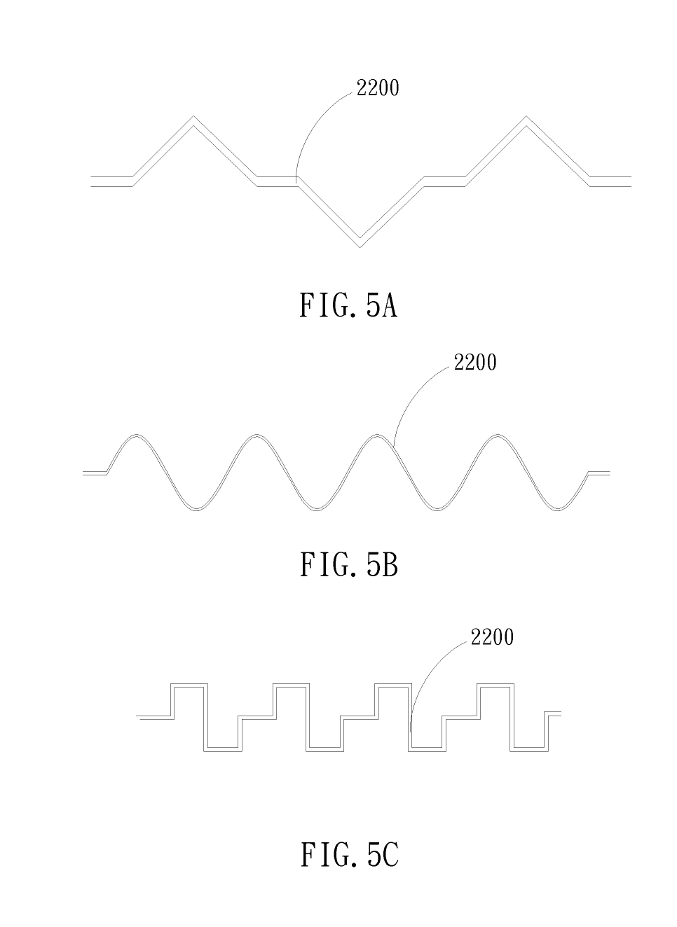

Referring to FIGS. 4A and 4B, they are schematic diagrams of a detection structure in the resistive touching area according to one embodiment of the present invention. In this embodiment, there are a plurality of detection areas 220 formed on the first conductive layer 230. Each one of detection areas 220 comprises a plurality of trenches 2200 and the trenches is distributed like a sine-wave curve. The first conductive layer 230 is divided into three electrodes 2201, 2202 and 2203 and any two of the electrodes form a capacity structure. Each one of the electrodes 2201, 2202 and 2203 coupled to a voltage source forms a capacity structure as shown in FIG. 4B. Also referring to FIGS. 5A, 5B and 5C which are schematic diagrams of a trench according to one embodiment of the present invention. The trench shown in FIG. 5A is like a triangular-wave curve. Also, the trenche shown in FIG. 5B is like a sine-wave curve. Further, the trench shown in FIG. 5C is like a square-wave curve.

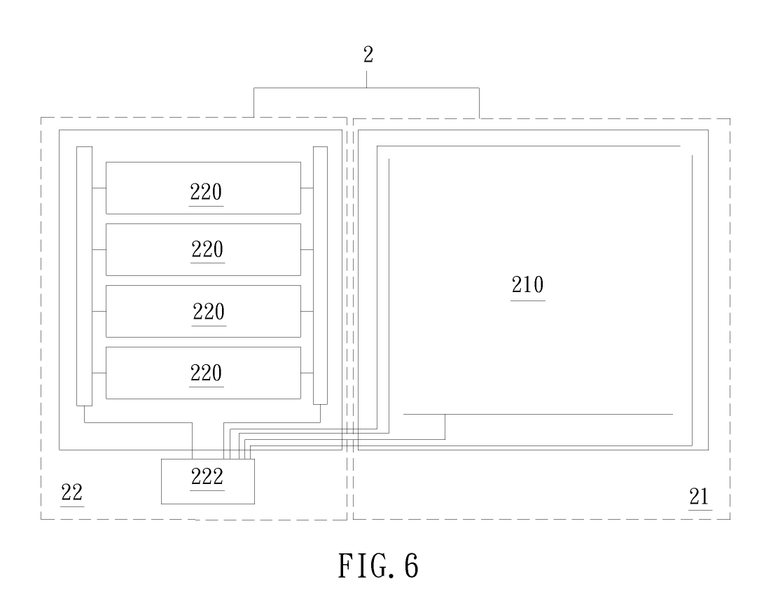

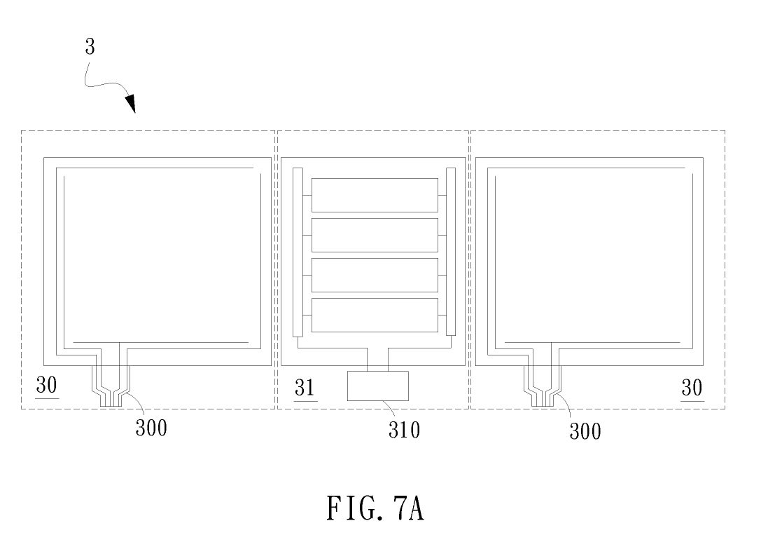

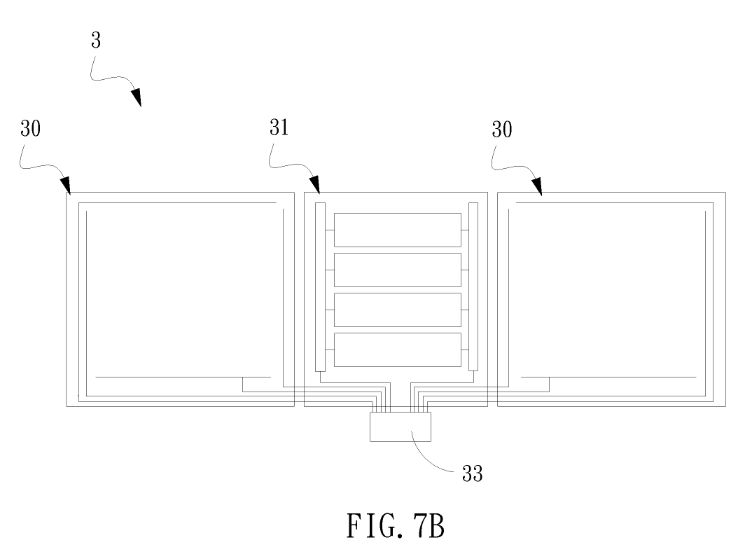

Referring to FIG. 6, it is a schematic diagram of a hybrid touch panel according to yet another embodiment of the present invention. In this embodiment, the resistive touch panel 21 and the capacitive touch panel are integrated in a transmission interface 222. Although one resistive touch panel and one capacitive touch panel is combined in this case, people skilled in the art should know multiple resistive touch panels and multiple capacitive touch panels could be combined together as the same way, for example, two resistive with two capacitive touch panels or two resistive with one capacitive touch panels. As shown in FIG. 7A, the hybrid touch panel 3 is a combination of two resistive touch panels and one capacitive touch panel. Each touch panel includes an independent transmission interface 300 and 310. Besides, multiple signal lines are integrated in an interface 33 as shown in FIG. 7B.

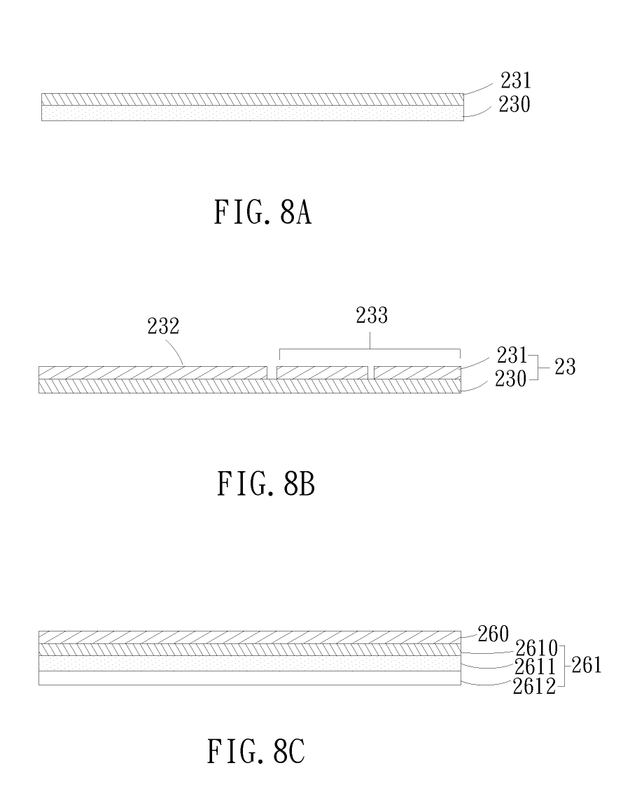

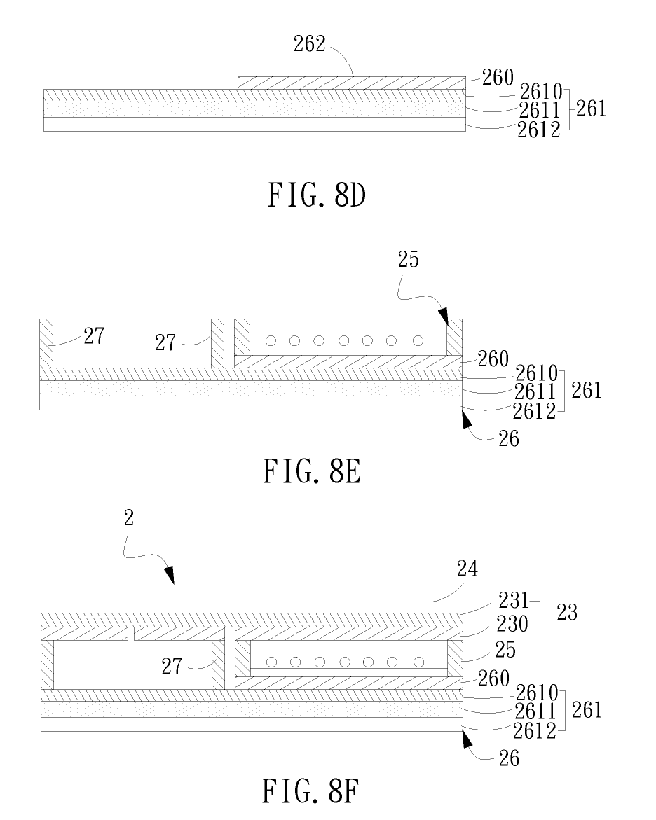

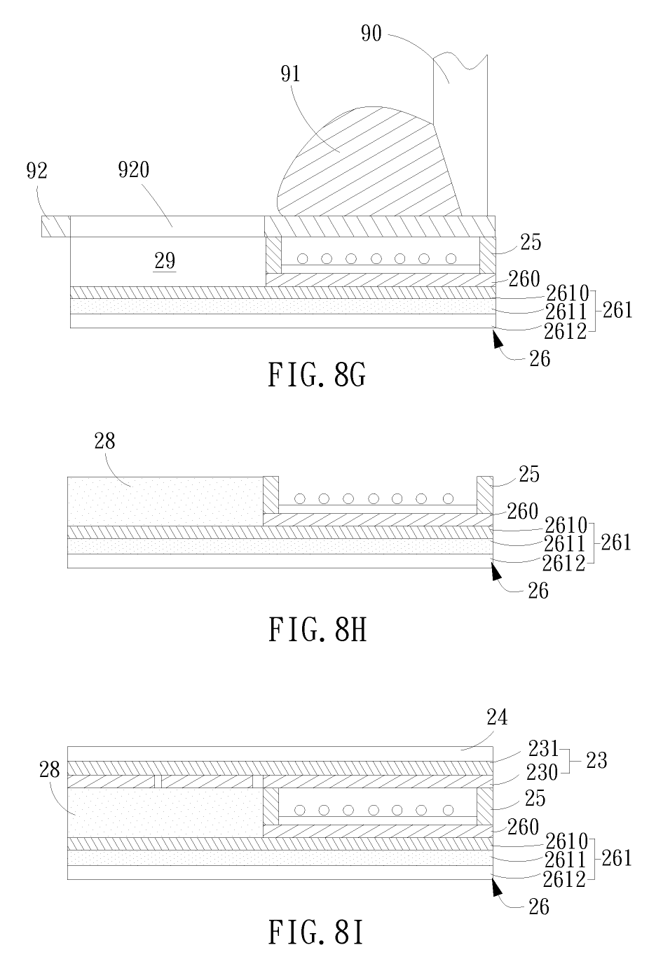

Referring to FIG. 8A-8I, which present a flow for illustration of making the hybrid touch panel according to one embodiment of the present invention. First, providing a base material 230 having a first conductive layer 231 as shown in FIG. 8A. Second, forming at least a first resistive touching area 232 and at least a capacitive touching area 233 by removing unnecessary conductive material on the first conductive layer 231, which constructs a first conductive module 23. There is a isolation area 234 between the first resistive touching area 232 and the capacitive touching area 233. Regarding the removing step could be a well-known art, etching method, which does not describe anymore. Furthermore, a printed metal like silver could be formed on the first conductive layer 231 for conductance.

The structure of the first resistive touching area 232 is the same as the structure as shown in FIG. 1A. The structure of the capacitive touching area 233 is the same as the structures as shown in FIG. 4A, 4B or FIG. 5 series. Following FIG. 8C, providing a base material 261 having a second conductive layer 260. Then FIG. 8D, forming at least a second resistive touch area 262 corresponding to the first resistive touch area 232 by removing unnecessary conductive material on the second conductive layer 260. Then FIG. 8E, forming an spacer layer 25 and an isolation structure 27 on the second resistive touching area 262, which constructs a second conductive module 26. The spacer layer 25 comprises a plurality of spacer dots. Finally, binding the first conductive module 23 and the second conductive module 26 to be a hybrid touch panel 2. A protection layer 24 like a polyester film could be formed on the first conductive layer 23 for protection.

Further, illustrating making method for the structure shown in FIG. 3. Basically, the steps described in FIGS. 8A to 8E are similar. Then processing the step shown in FIG. 8G. Utilizing a module board 92 to cover the second conductive module 26 shown in FIG. 8E. The opening 920 of the module board 92 corresponds to a space 29 of the second conductive module 26. Filling the space 29 with an optical adhesive by a scraping cutter to form the structure shown in FIG. 8H. Finally, binding the first conductive module 23 and the second conductive module 26 to form the structure as shown in FIG. 8I.

Methods and systems of the present disclosure, or certain aspects or portions of embodiments thereof, may take the form of program code (i.e., instructions) embodied in media, such as floppy diskettes, CD-ROMS, hard drives, firmware, or any other machine-readable storage medium, wherein, when the program code is loaded into and executed by a machine, such as a computer, the machine becomes an apparatus for practicing embodiments of the disclosure. The methods and apparatus of the present disclosure may also be embodied in the form of program code transmitted over some transmission medium, such as electrical wiring or cabling, through fiber optics, or via any other form of transmission, wherein, when the program code is received and loaded into and executed by a machine, such as a computer, the machine becomes an apparatus for practicing and embodiment of the disclosure. When implemented on a general-purpose processor, the program code combines with the processor to provide a unique apparatus that operates analogously to specific logic circuits.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A hybrid touch panel, comprising:
a first conductive module including a first conductive layer having at least a first resistive touching area, and at least a capacitive touching area;
a second conductive module including a second conductive layer having at least a second resistive touching area corresponding to the first resistive touching area respectively; and
a spacer layer coupled to the first resistive touching area and the second resistive touching area has spacer dots disposed therebetween.

2. The hybrid touch panel as claimed in claim 1, wherein the first conductive module further comprises a base material coupled to the first conductive layer.

3. The hybrid touch panel as claimed in claim 2, wherein the base material is a polyester film.

4. The hybrid touch panel as claimed in claim 1, wherein the second conductive module further comprises a base material coupled to the second conductive layer.

5. The hybrid touch panel as claimed in claim 4, wherein the base material is a polyester film.

6. The hybrid touch panel as claimed in claim 4, wherein the base material further comprises:
a substrate;
an optical adhesive layer formed on the substrate; and
a polyester film layer formed on the optical adhesive and coupled to the second conductive layer.

7. The hybrid touch panel as claimed in claim 6, wherein material of the substrate is a polycarbonate.

8. The hybrid touch panel as claimed in claim 1, wherein the capacitive touching area further comprises at least an induced area, the induced area is divided into a plurality of electrodes by a plurality of trenches and any two of neighboring electrodes construct a flat capacity structure.

9. The hybrid touch panel as claimed in claim 8, wherein trenches a functional curve, the functional curve is selected from a group consisting of a square-wave curve, a triangular-wave curve and a sine-wave curve.

10. The hybrid touch panel as claimed in claim 1, wherein an isolation structure is formed between the capacitive touching area and the second conductive module.

11. The hybrid touch panel as claimed in claim 1, wherein the first conductive module further comprises a protection layer.

12. The hybrid touch panel as claimed in claim 11, wherein the protection layer is a polyester film.

13. A method for making a hybrid touch panel, comprising:
providing a base material having a first conductive layer;
forming at least a first resistive touching area and at least a capacitive touching area by removing unnecessary conductive material on the first conductive layer, which constructs a first conductive module;
providing a base material having a second conductive layer;
forming at least a second resistive touch area corresponding to the first resistive touch area by removing unnecessary conductive material on the second conductive layer;
forming an isolation layer on the second resistive touching area, which constructs a second conductive module; and
binding the first conductive module and the second conductive module.

14. The method as claimed in claim 13, wherein the base material is a polyester film.

15. The method as claim in claim 13, wherein the base material further comprises:
a substrate;
an optical adhesive formed on the substrate; and
a polyester film layer formed on the optical adhesive and coupled to the second conductive layer.

16. The method as claim in claim 15, wherein material of the substrate is a polycarbonate.

17. The method as claim in claim 13, wherein the capacitive touching area further comprises at least an induced area, the induced area is divided into a plurality of electrodes by a plurality of trenches and any two of neighboring electrodes construct a flat capacity structure.

18. The method as claim in claim 17, wherein trenches a functional curve, the functional curve is selected from a group consisting of a square-wave curve, a triangular-wave curve and a sine-wave curve.

19. The method as claim in claim 13, further comprises a step of forming an optical adhesive layer or an UV adhesive on the second conductive module.

20. The method as claim in claim 13, further comprises a step of forming an isolation structure on the second conductive module corresponding to the capacitive touching area.

21. The method as claim in claim 13, further comprises a step of forming a protection layer on the first conductive layer.

22. The method as claim in claim 21, wherein the protection layer is a polyester film.
